(19) United States
(12) Patent Application Publication
(10) Pub. No.: US 2003/0221782 A1
(43) Pub. Date: Dec. 4, 2003

(54) Structural improvement for wafer supporting apparatus

(75) Inventor: Yu-Chih Chang, Hsinchu (TW)

Correspondence Address: BRUCE H. TROXELL, SUITE 1404, 5205 LEESBURG PIKE, FALLS CHURCH, VA, 22041, US

(73) Assignee: M.D. TECHNOLOGY, INC.

(21) Appl. No.: 10/154,805

(22) Filed: May 28, 2002

(51) Int. Cl. C23F 1/00; C23C 16/00

(52) U.S. Cl. 156/345.48; 118/723 I

(57) ABSTRACT

The invention is a structural improvement for wafer supporting apparatus, which is applied in a machine capable of providing a support for a wafer during a manufacturing process of semiconductor.

The wafer supporting apparatus, disclosed in the invention, includes: a separating seat, a metallic seat, an upper cover, several antennas, and several antenna masks. Wherein, the separating seat may provide a support to the structure of the wafer supporting apparatus, and the upper cover may accommodate the metallic seat therein and is then covered over the separating seat, and the wafer may be put on the upper cover, and the several antennas are placed in the several side recessing holes preset in the side of the separating seat, and the antenna masks cover the antennas for protection and isolate them from outside to avoid the particles to be deposited and attached thereon during the manufacturing process.

### 1. FIELD OF THE INVENTION

The invention relates to a structural improvement for wafer supporting apparatus, which is applied in a machine for supporting wafer in conjunction with the manufacturing process of semiconductor, especially to a protecting mask of antenna apparatus, which keeps the impurities and particles from being deposited thereon.

### 2. BACKGROUND OF THE INVENTION

The technology of the industry of semiconductor is changing with each passing day, while the complication of the manufacturing process of semiconductor is also known to everybody, wherein the techniques and facilities relative to the deposition of membrane are further crucial to the entire manufacturing process. For example, the manufacturing process of membrane of the metallic deposition on the Endura operative platform has integrated several reactive partitions, in which a reactive partition for pre-cleaning is included, and a supporting platform in conjunction with the wafer is further designed in the reactive partition for pre-cleaning.

Please refer to FIG. 1, which is an illustration for the supporting apparatus of wafer according to the prior arts. As shown in FIG. 1, a supporting apparatus of wafer includes: a separating seat 10, a metallic seat 11, an upper cover 12, and several antennas 13. Wherein, the separating seat 10 may be available to the metallic seat 11 to be placed in, and the upper cover 12 is then covered on the separating seat 10 and accommodates the metallic seat 11 therein, and the wafer 3 is thus placed on the upper cover 12. The several antennas 13 are inserted toward the central portion from the side of the separating seat 10. By the radio frequency (RF) passing through the metallic seat 11, the antennas 13 will form a transmission path to produce an influence on the entire manufacturing process as well as the wafer 3.

Through the connecting relationship between the antennas 13 and the metallic seat 11, a value of impedance may be formed, and another value of impedance may also be formed between the metallic seat 11 and the wafer 3. Such design may have a lower etching rate and the antennas may have a higher value of DC voltage.

However, during the process of depositing membrane onto the wafer 3, the process acting on the wafer 3 by applying the radio frequency of extremely high voltage will produce a lot of overflowing particles to be accumulated. These particles will be deposited or attached onto the antennas and will be accumulated partially on one outside end thereof. Such kind of phenomenon will produce bad influence on the antennas 13. For a long time, it will influence the quality and the function of the entire manufacturing process. Under this condition, if several protecting designs may be made on the antennas to keep the particles from being deposited or attached thereon in the manufacturing process, then the using life of the antennas will be prolonged and the yield of the entire manufacturing process will be further ensured.

### SUMMARY OF THE INVENTION

The present invention is thus designed for solving the shortcomings generated from the prior arts as described above. The present invention is a structural improvement for wafer supporting apparatus, which is applied in the procedure of membrane deposition in the manufacturing process of semiconductor. The main object of the present invention is thus to solve the shortcomings of the prior arts; namely, the antenna is vulnerable to the deposition and attachment of the particles of impurity in the manufacturing process of semiconductor, and the using life is reduced, so an appropriate apparatus for masking the antenna is designed on the purpose of protection.

Another object of the present invention is to propose a design aimed to simply and facilitate the usage of the apparatus for masking the antenna, and an improvement is further made on the original supporting machine without influencing its function, such that any unnecessary, tedious procedure and flow path may be further reduced during the progress of manufacturing process. That is, the cost may not be increased substantially, while its original function can be kept and its effectiveness can be developed extremely. In the meantime, the time and cost in the manufacturing process is further reduced and the using life of the antenna is thus prolonged for raising the yield of the production of the wafer.

The wafer supporting apparatus disclosed in the present invention includes: a separating seat, a metallic seat, an upper cover, several antennas, several antenna masks and several fixing apparatus. Wherein, the separating seat may provide a support to the structure of the wafer supporting apparatus, and the upper cover may accommodate the metallic seat therein and is then covered over the separating seat, and the wafer may be put on the upper cover. The several antennas are placed in the several side recessing holes preset in the side of the separating seat and are inserted in the central portion of the separating seat. Wherein, the metallic seat is made of titanium metal, and the separating seat and the upper cover are composed of quartz material. The antenna masks cover the antennas for protection and isolates them from outside.

Preferably, the antenna masks are structured as an “L” shape, which may cover the antennas from the top and the back thereof to isolate them from outside to further prevent them from touching particles of impurity in the manufacturing process.

Preferably, several apertures arranged in the upper portion of the antenna masks are provided for the fixing apparatus to fix the antenna masks on the separating seat, and the fixing apparatus may be composed of quartz material.

Preferably, the antenna masks may cover the antennas from the back thereof to isolate them from outside, and several fixing apparatuses are applied for fixation.

Preferably, the antenna masks are structured as a “ [symbol] ” shape and cover the antennas from the top, bottom, and back thereof to isolate them from outside, and the antenna masks have threads that may screwed the antenna masks in the apertures preset in the separating seat.

For your esteemed members of reviewing committee to further understand and recognize the objects, the characteristics, and the functions of the present invention, a detailed description matched with corresponding drawings are presented as follows.

### BRIEF DESCRIPTION OF THE DRAWINGS

FIG. 1 is an illustration for a wafer supporting apparatus according to the prior arts.

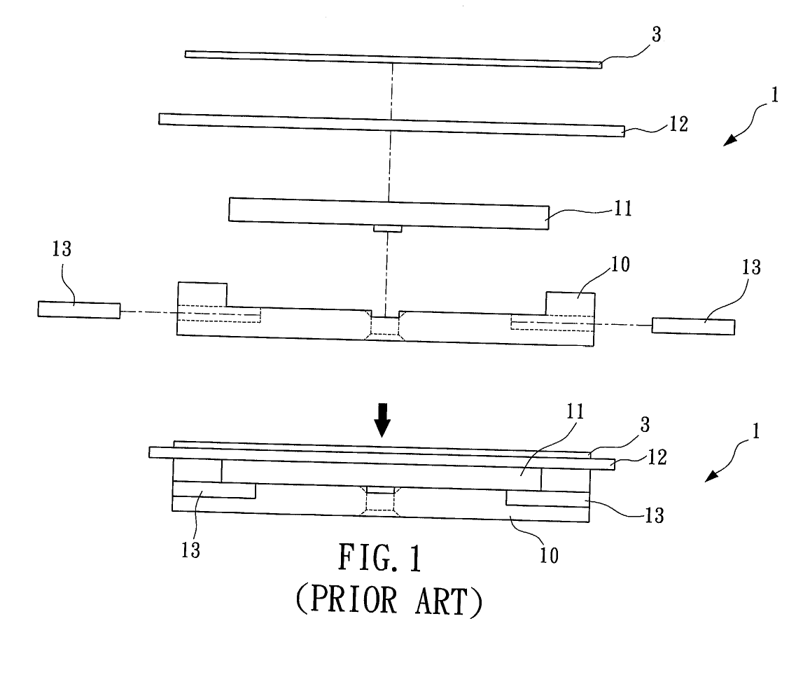

FIG. 2 is an illustration for the assembly of the first preferred embodiment according to the present invention.

FIG. 3 is an illustration for the assembly of the second preferred embodiment according to the present invention.

FIG. 4 is an illustration for the assembly of the third preferred embodiment according to the present invention.

### DETAILED DESCRIPTION OF THE INVENTION

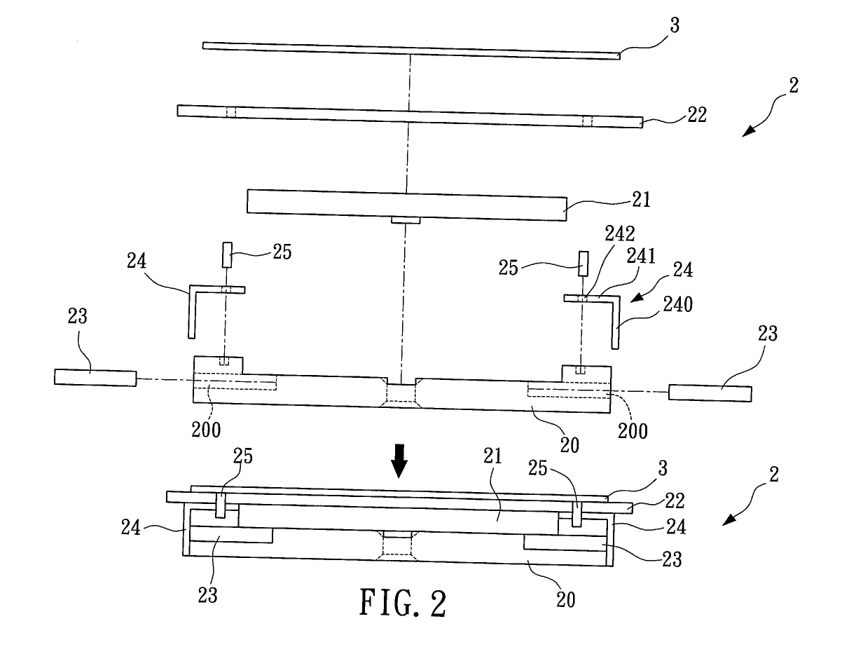

Please refer to FIG. 2, which is an illustration for the assembly of the first preferred embodiment according to the present invention. As shown in FIG. 2, the wafer supporting apparatus 2 includes: a separating seat 20, a metallic seat 21, an upper cover 22, several antennas 23, several antenna masks 24 and several fixing apparatus 25. Wherein, the separating seat 20 may provide a support to the structure of the wafer supporting apparatus, and the metallic seat 21 may be placed thereon, and the upper cover 22 is then covered over the separating seat 20 and may accommodate the metallic seat 11 therein, and the wafer 3 may be put on the upper cover 22. The several antennas 23 are placed in the several side recessing holes 200 preset in the side of the separating seat 20 and are inserted in the central portion of the separating seat 20. Wherein, the metallic seat 21 is composed of titanium metal, and the separating seat 20 and the upper cover 22 are composed of quartz material.

Wherein, the antenna masks are structured as an “L” shape. When the antennas 23 are placed in the side recessing holes 200 of the outside of the separating seat 20, the antenna masks 24 then cover the antennas 23 from the top and back thereof to mask the several antennas 23 and isolate them from outside to further prevent them from touching particles in the manufacturing process. The upper portions 241 of the antennas 24 are arranged with apertures 242, and the fixing apparatus 25, through the upper cover 22, penetrating through the upper portions 241 of the antenna masks, and the apertures 242, are fixed on the separating seat 20, and the fixing apparatus 25 may be constructed of quartz material. Since the antennas 23 are masked by the side portions 240 of the antenna masks 24, so the particles are blocked from dispersing and depositing in the manufacturing process and, of course, the antennas 23 are also prevented from being etched and damaged by the chemical material. Preferably the antenna masks 24 and the fixing apparatus 25 can be made to a single structure.

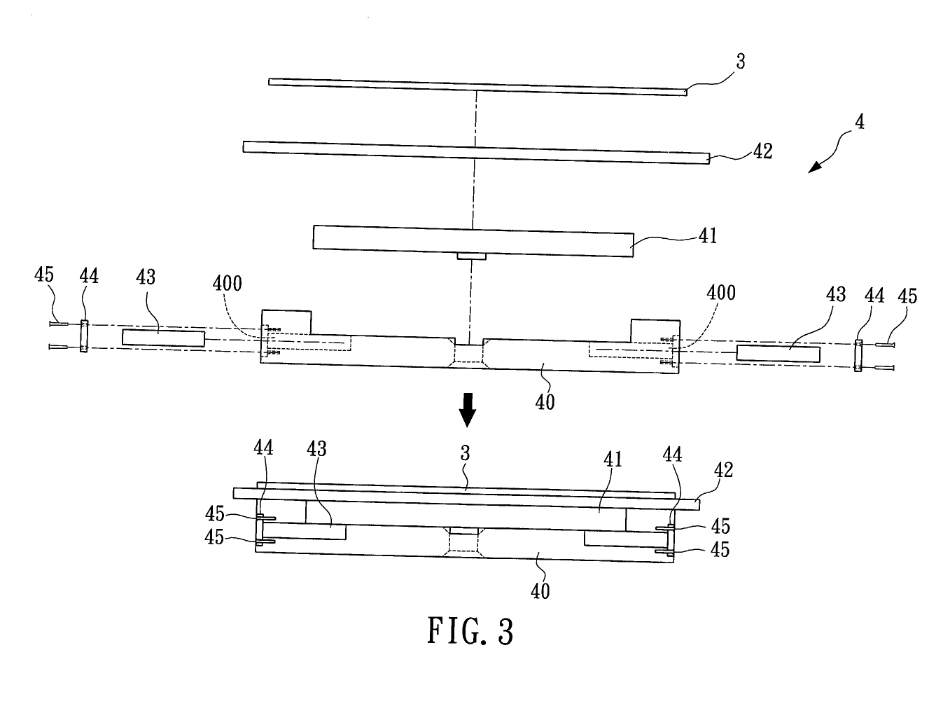

Please refer to FIG. 3, which is an illustration for the assembly of the second preferred embodiment according to the present invention. As shown in FIG. 3, wherein the separating seat 40, the metallic seat 41, and the upper cover 42 are all same as those of FIG. 2 described previously. However, in this preferred embodiment, there is another kind of preferable design for the structures of the several antennas 43, the several antenna masks 44, and the several fixing apparatus 45. In this preferable embodiment, after the antennas 43 being placed into the side recessing holes 405 of the outside of the separating seat 40, the antennas 43 are then covered by the antenna masks 44 from the back thereof. Matched with the design of the separating seat 40, the antenna masks 44 may be inset on the separating seat 40, or the antenna masks 44 may be screwed from the back toward the front by the fixing apparatus 45.

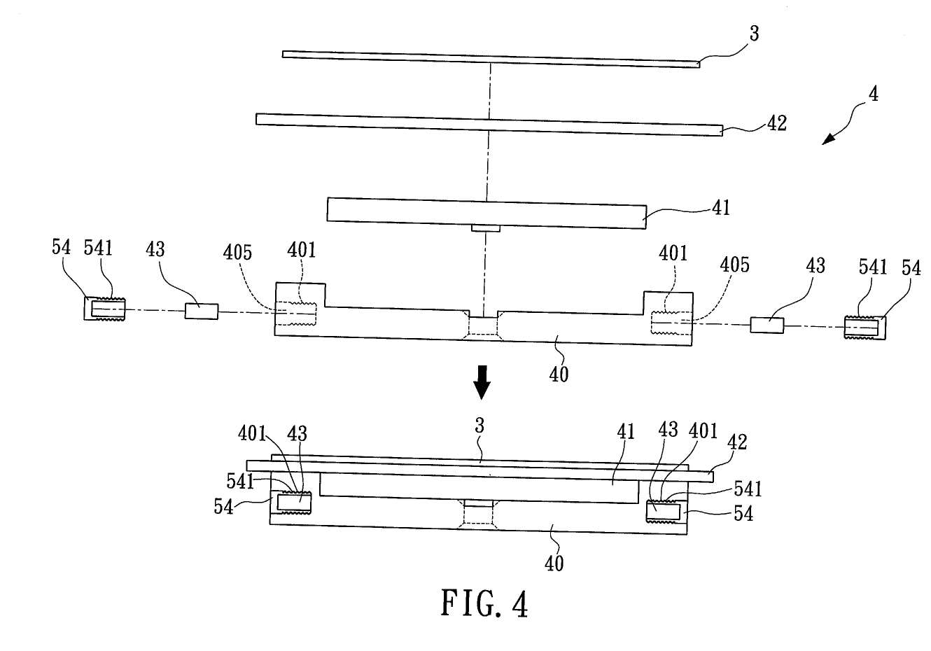

Please refer to FIG. 4, which is an illustration for the assembly of the third preferred embodiment according to the present invention. As shown in FIG. 4, wherein the separating seat 40, the metallic seat 41, and the upper cover 42 are all same as those of FIG. 2 described previously. In this preferable embodiment, the antenna masks are structured as a “ [symbol] ” shape, and there are threads 541 arranged at the appropriate positions of the upper arm and the lower arm thereof. Furthermore, there are threads 401 designed in the appropriate positions of the side recessing holes 405 of the outside of the separating seat 40 for placing the antennas 43 in corresponding to the threads 541 arranged at the upper arm and the lower arm of the antenna masks 54. When the antennas 43 are placed in the side recessing holes 405 of the outside of the separating seat 40, the antennas 43 are screwed by the antenna masks 54 from the top, bottom, and back thereof, namely, the antenna masks are thus similar to a “ [symbol] ”-shaped antenna masks having the functional principle of a nut to mask the antennas 43 and isolate them from outside.

Wherein the arranging position and the number of round of the thread are dependent and considered on the real size, length of the antenna and the design of the entire separating seat, and it can be that the antennas are covered to isolate themselves from outside, as long as the antenna are placed appropriately. Of course, the manufacturing materials of the antenna masks should be appropriately considered as the materials resistant to the erosive particles or chemicals produced from the manufacturing process of semiconductor, such as the usage of quartz material.

From the preferred embodiments described above, it is known that the spirit of the present invention is to provide a mask of protection for the antenna to avoid the antenna from being damaged, shortening life, and even the influence on the yield of the production of the entire wafer due to the deposition of the particles in the manufacturing process of semiconductor. Therefore, for all the several masking executions designed for the apparatus of the antennas, such as the similar structures of the several masking apparatus or protecting apparatus, they should be considered as the designs foreseen by the present invention. Furthermore, the present invention is of course not limited in the manufacturing process of the deposition of the membrane, and it can also be applied in the all relative processes of semiconductor, such as etching, cleaning, and depositing, etc., where the wafer supporting machine or the operative platform are utilized.

From above description, the technique disclosed in the present invention has been productive and innovative and also has extremely applying value for the industry. Any variation and modification within the spirit of the present invention or made from the appendant claims are all covered by the scope of the present invention. Sincerely, your esteemed members of reviewing committee could examine the present application favorably and permit it as a formal patent wishfully.

What is claimed is:

1. A structural improvement for wafer supporting apparatus, which may be applied in a manufacturing process of semiconductor, and which includes:
a separating seat, which may provide a support to the structure of the wafer supporting apparatus;
a metallic seat, which may be placed on the separating seat;
an upper cover, which may cover the metallic seat on the separating seat, and over which a wafer may be placed;
several antennas, which may be inserted into several apertures that are preset in the side of the separating seat; and
several antenna masks, which are arranged with respect to the several antennas on the purpose to mask the several antennas.

2. The structural improvement for wafer supporting apparatus according to claim 1, wherein said antenna masks cover the antennas from the top and the back of the antennas.

3. The structural improvement for wafer supporting apparatus according to claim 1, wherein said antenna masks are structured as an “L” shape.

4. The structural improvement for wafer supporting apparatus according to claim 1, wherein it further includes several fixing apparatuses, which may fix the antennas masks.

5. The structural improvement for wafer supporting apparatus according to claim 1, wherein said antenna masks cover the antennas from the back of the antennas.

6. The structural improvement for wafer supporting apparatus according to claim 1, wherein said antenna masks cover the antennas and are inset together with the separating seat.

7. The structural improvement for wafer supporting apparatus according to claim 1, wherein there are threads arranged in the preset apertures of said separating seat.

8. The structural improvement for wafer supporting apparatus according to claim 1, wherein said antennas are structured as a “ [symbol] ” shape.

9. The structural improvement for wafer supporting apparatus according to claim 1, wherein there are threads arranged in said antenna masks.

10. The structural improvement for wafer supporting apparatus according to claim 1, wherein said separating seat is made of quartz material.

11. The structural improvement for wafer supporting apparatus according to claim 1, wherein said metallic seat is made of titanium metal.

12. The structural improvement for wafer supporting apparatus according to claim 1, wherein said upper cover is made of quartz material.

13. The structural improvement for wafer supporting apparatus according to claim 4, wherein said fixing apparatuses are made of quartz material.

14. The structural improvement for wafer supporting apparatus according to claim 1, wherein said antenna masks are made of quartz material.
